(19) United States
(12) Patent Application Publication
(10) Pub. No.: US 2026/0180609 A1
(43) Pub. Date: Jun. 25, 2026

(54) FREQUENCY MULTIPLIER IN RADIO FREQUENCY CIRCUIT

(71) Applicant: TP-LINK SYSTEMS, INC., Irvine, CA (US)

(72) Inventors: Taewook Kim, San Jose, CA (US); Changhui Hu, Sunnyvale, CA (US)

(73) Assignee: TP-LINK SYSTEMS, INC., Irvine, CA (US)

(21) Appl. No.: 19/000,588

(22) Filed: Dec. 23, 2024

(51) Int. Cl. H04B 1/40; H03F 3/24

(52) U.S. Cl. CPC H04B 1/40; H03F 3/245; H03F 2200/451

(57) ABSTRACT

In an embodiment, a radio frequency circuitry includes one or more transceivers and a frequency multiplier. The frequency multiplier is coupled to the one or more transceivers to provide a high frequency signal based in part on a local oscillator signal. The frequency multiplier includes: a multi-phase generator and an edge combiner. The multi-phase generator includes a plurality of output lines and is configured to generate a plurality of delayed signals respectively at the plurality of output lines, each delayed signal having a respective delay with respect to the local oscillator signal. The edge combiner is coupled to the multi-phase generator and configured to provide the high frequency signal based in part on a rising edge or a falling edge in the plurality of delayed signals. The frequency multiplier can be implemented in any access point or client device in a wireless communication network such as IEEE 802.11.

### FIELD

This technology relates to wireless communication network, and more particularly to frequency multiplier in radio frequency circuitry.

### BACKGROUND

In wireless communication, radio frequency (RF) circuitry is used to receive and transmit RF signals from/to the air. Depending on the given protocol, the RF signals can be in high frequency, e.g., in the gigahertz range. For example, wireless local area network (WLAN) protocols, such as Institute for Electrical and Electronics Engineers (IEEE) 802.11, allow for transmission of RF signals in 2.4 GHz and 5 GHz. As such, RF circuitry or components thereof, e.g., receivers or transmitters, need to operate in high frequencies. Typically in RF circuitry, stable high frequency signals are provided, e.g., using a local oscillator.

In RF circuitry, high frequency signals may be generated using a voltage controlled oscillator (VCO) and frequency multiplier that multiplies the frequency generated by the VCO, and transmitted to a transceiver (including receiver and transmitter). Providing high frequency signals to receivers or transmitters may require distributing local oscillator high frequency signals over a distance (e.g., a few millimeters), which may degrade the signals. Thus, high frequency boosting techniques may be used before high frequency signals are provided to receivers or transmitters.

### SUMMARY

The present disclosure relates to techniques for frequency multiplier. In an embodiment, an apparatus for communication in a wireless network, the apparatus includes a radio frequency (RF) circuitry. The RF circuitry includes one or more transceivers respectively coupled to one or more antennas to transmit or receive RF signals, wherein each of the one or more transceivers is configured to convert between the RF signals and baseband signals based in part on a high frequency signal. The RF circuitry further comprises a frequency multiplier coupled to the one or more transceiver and configured to provide the high frequency signal based in part on a local oscillator signal. The high frequency signal has a frequency that is odd-numbered multiplication of that of the local oscillator signal. The frequency multiplier comprises: a multi-phase generator and an edge combiner coupled to the multi-phase generator. The multi-phase generator comprises a plurality of output lines and is configured to generate a plurality of delayed signals respectively at the plurality of output lines, each delayed signal having a respective delay with respect to the local oscillator signal. The edge combiner is configured to provide the high frequency signal based in part on a rising edge or a falling edge in the plurality of delayed signals.

In an embodiment, a radio frequency (RF) circuitry includes: one or more transceivers respectively coupled to one or more antennas to transmit or receive RF signals, wherein each of the one or more transceivers is configured to convert between the RF signals and baseband signals based in part on a high frequency signal. The RF circuity further includes a frequency multiplier coupled to the one or more transceiver and configured to provide the high frequency signal based in part on a local oscillator signal, where the high frequency signal has a frequency that is odd-numbered multiplication of that of the local oscillator signal. The frequency multiplier includes: a multi-phase generator and an edge combiner coupled to the multi-phase generator. The multi-phase generator includes a plurality of output lines and configured to generate a plurality of delayed signals respectively at the plurality of output lines, each delayed signal having a respective delay with respect to the local oscillator signal. The edge combiner is configured to provide the high frequency signal based in part on a rising edge or a falling edge in the plurality of delayed signals.

In an embodiment, a frequency multiplier for use in a wireless transceiver includes a multi-phase generator and an edge combiner coupled to the multi-phase generator. The multi-phase generator includes a plurality of output lines and is configured to generate a plurality of delayed signals respectively at the plurality of output lines, each delayed signal having a respective delay with respect to a first signal. The edge combiner is configured to provide a second signal based in part on a rising edge or a falling edge in the plurality of delayed signals, where the second signal has a frequency that is odd-numbered multiplication of that of the first signal.

### BRIEF DESCRIPTION OF DRAWINGS

Additional embodiments of the disclosure, as well as features and advantages thereof, will become more apparent by reference to the description herein taken in conjunction with the accompanying drawings. The components in the figures are not necessarily to scale. Moreover, in the figures, like-referenced numerals designate corresponding parts throughout the different views.

FIG. 1 illustrates a wireless communication network, according to some embodiments.

FIG. 2 is a schematic diagram of an example RF circuit including two or more transceivers, according to some embodiments.

FIG. 3 is a schematic diagram of an example high frequency multiplier, according to some embodiments.

FIG. 4 is a schematic diagram of a multi-phase generator that can be used in a frequency tripler, according to some embodiments.

FIG. 5A is a schematic diagram of an edge combiner that can be used in a frequency tripler, according to some embodiments.

FIG. 5B illustrates example signals in an edge combiner, according to some embodiments.

FIGS. 6A-6B show comparison of simulated spur levels between prior art existing frequency tripler and example frequency tripler, according to some embodiments.

### DETAILED DESCRIPTION

For the purposes of promoting an understanding of the principles of the present disclosure, reference will now be made to the embodiments illustrated in the drawings, and specific language will be used to describe the same. It will nevertheless be understood that no limitation of the scope of the invention is thereby intended. It should be further appreciated that the embodiments described herein may be implemented in any of numerous ways. Examples of specific implementations are provided below for illustrative purposes only. It should be appreciated that these embodiments and the features/capabilities provided may be used individually, all together, or in any combination of two or more, as aspects of the technology described herein are not limited in this respect.

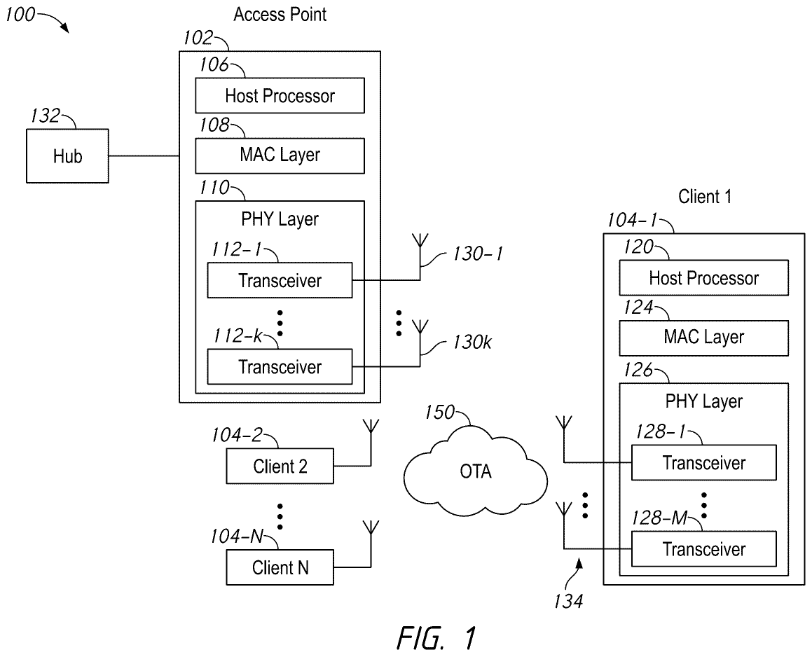

FIG. 1 illustrates a wireless communication network, according to some embodiments. In some embodiments, a wireless communication network 100 (e.g., WLAN) may facilitate communications between one or more access point (AP) device (e.g., 102) and one or more client devices (e.g., 104-1, 104-2, . . . 104-N). Each of the AP and client devices may be configured to receive or transmit frames (packets) from/to another device (e.g., AP or client devices) via over the air (OTA) medium (e.g., 150). These communication devices may be communicating with each other in a communication protocol, e.g., IEEE 802.11, or other suitable wireless protocols.

As shown in FIG. 1, AP device 102 may include one or more antennas (e.g., 130-1, . . . 130-K) configured to transmit or receive radio frequency (RF) signals to/from other devices in the wireless communication network 100. AP device 102 may include a physical layer 110, a MAC layer 108, and a host processor 106, which are configured to generate or process RF signals in lower to upper network layers, respectively. For example, PHY 110 may be configured to implement physical layer functions. PHY 110 may also include one or more transceivers (e.g., 112-1, . . . 112-K) configured to convert between baseband signals and RF signals, where RF signals are transmitted or received via the one or more antennas, e.g., 130-1, . . . 130-K.

In FIG. 1, the MAC 108 may be configured to implement MAC layer functions including processing frames (packets) received from the PHY layer and converting to data frames for upper layer(s), or vice versa. Host processor 106 may be coupled to MAC 108 and PHY 110 to process data via respective layers. Host processor 106 may also be configured to implement one or more applications and transmit/receive data to/from MAC 108.

As shown in FIG. 1, each of the components, e.g., host processor 106, MAC 108, PHY 110, as well as transceivers (112-1, . . . 112-K) may include circuitry, e.g., one or more integrated circuits (ICs). Thus, one or more functions of MAC and PHY layers may be implemented in hardware. Alternatively, and/or additionally, one or more functions of MAC and PHY layers may be implemented in software, e.g., via executing programing instructions (e.g., stored in memory). For example, each of the MAC 108 and PHY 110 may include one or more processors, e.g., CPUs, to execute programming instructions in a memory.

With further reference to FIG. 1, AP device 102 may be connected to a hub 132 (e.g., a wired router, a modem) which provides the Internet services (e.g., via an ISP). AP device 102 may provide Internet, via hub 132, to one or more client devices (e.g., 104-1, 104-2, . . . 104-N) that are connected to the AP device wirelessly, e.g., via OTA medium 150. Each of the client devices may have a similar configuration as the AP device 102. For example, client device 104-1 may include a host processor 120, a MAC layer 124, a PHY layer 126.

Similar to AP device 102, a client device (e.g., 104-1, 104-2, . . . 104-N) may include one or more antennas (e.g., 134) configured to transmit or receive RF signals to/from other devices in the wireless communication network 100. PHY layer 126, MAC layer 124, and host processor 120 may be configured to generate or process RF signals in lower to upper network layers, respectively. For example, PHY layer 126 may be configured to implement physical layer functions. PHY layer 126 may include one or more transceivers (e.g., 128-1, . . . 128-M) configured to convert between baseband signals and RF signals, where RF signals are transmitted or received via the one or more antennas 134.

In FIG. 1, MAC layer 124 may be configured to implement MAC layer functions including processing frames (packets) received from the PHY layer and converting to data frames for upper layer(s), or vice versa. Host processor 120 may be coupled to the MAC layer 124 and PHY layer 126 to process data via respective layers. Host processor 120 may also be configured to implement one or more applications and transmit/receive data to/from MAC layer 124.

Similar to AP device 102, each of the components in a client device, e.g., host processor 120, MAC layer 124, PHY layer 126, as well as transceivers (128-1, . . . 128-M) may include circuitry, e.g., one or more integrated circuits (ICs). Thus, one or more functions of MAC and PHY layers may be implemented in hardware. Alternatively, and/or additionally, one or more functions of MAC and PHY layers may be implemented in software, e.g., via executing programing instructions (e.g., stored in memory) by MAC layer 124, PHY layer 126, host processor 120, or any other suitable processors. Client devices 104-2, . . . 104-N may each have a similar configuration as client device 104-1. Although one AP device 102 is shown in FIG. 1, it is appreciated that there can be multiple AP devices in the wireless communication network 100. Further, any suitable number of client device may be possible as supported in current or later developed protocols.

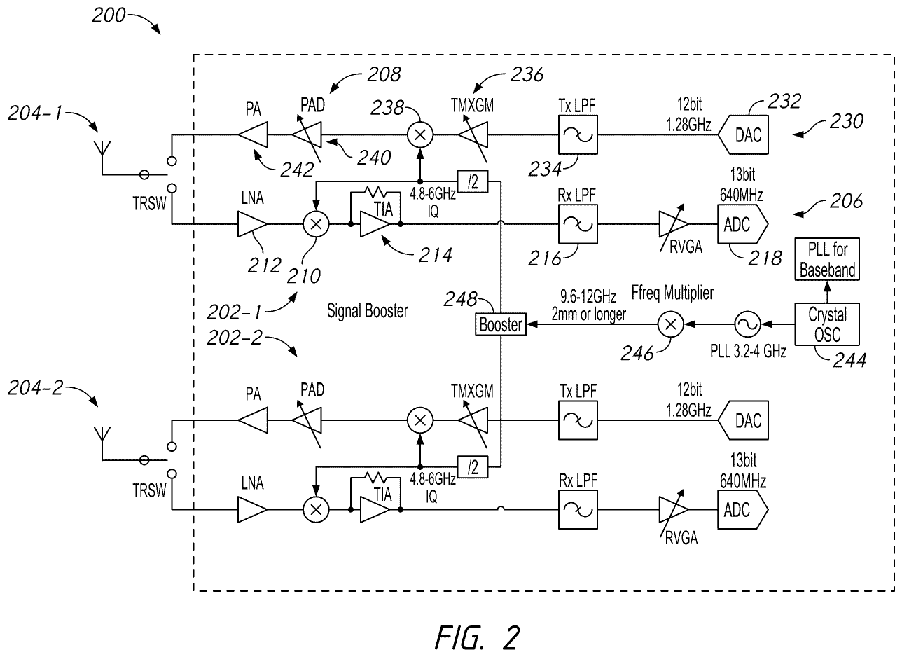

A device in the wireless network 100 (e.g., 102, 104) may thus have RF circuit including one or more transceivers (including receivers and transmitters) respectively coupled to one or more antennas. FIG. 2 is a schematic diagram of an example RF circuit 200 including two or more transceivers, according to some embodiments. In some embodiments, RF circuit 200 may be implemented in transceiver(s) of any wireless communication device (e.g., 112, 128 in FIG. 1). In the example configuration shown in FIG. 2, RF circuit 200 includes transceiver 202-1, 202-2, respectively coupled to antennas 204-1, 204-2. In these transceivers, high frequency signal may be mixed with incoming RF signal to provide a new signal at an intermediate frequency for processing before digitized via analog-to-digital converter (ADC). Conversely, the digital signal to be transmitted is converted to analog signal via digital-to-analog converter (DAC), then modulated with high frequency signal, e.g., 5 GHz to be transmitted to OTA via a corresponding antenna.

In non-limiting examples in FIG. 2, transceiver 202-1 may include a receiver 206 and transmitter 230. Receiver 206 may include mixer 210 configured to demodulate the incoming RF signal with a high frequency signal (e.g., downconvert RF signal to baseband signal for processing). Receiver 206 may further process the demodulated signal. For example, receiver 206 may include a low noise amplifier (LNA, 212) coupled to mixer 210, which may be coupled to a transimpedance amplifier (TIA, 206). Receiver 206 may further include ADC 218 to digitize the processed analog signal into digital signal. In some embodiments, receiver low pass filter (Rx LPF, 216) and receiver variable gain amplifier (RVGA, 220) may be provided to process the signal from TIA 206 before being digitized at ADC 218.

In FIG. 2, transmitter 230 may include DAC 232 configured to convert digital signal to be transmitted into analog signal. Transmitter low pass filter (Tx LPF, 234) may be coupled to DAC 232 may be coupled to Tx LPF 234 and mixer 238, which may be configured to modulate signal with a high frequency signal (e.g., upconvert a baseband signal to RF signal for transmission). Transmitter 230 may include power amplifier (PA, 242) and/or power amplifier driver (PAD, 240) to drive the modulated signal at an appropriate power for transmission. In some embodiments, transmitter 230 may also include a transmitter mixer gm (TMXGM, 236) coupled to the Tx LPF 234 and the mixer 238. Other transceiver(s), e.g., 202-2 may be configured in a similar manner as transceiver 202-1.

In some embodiments, the high frequency signal provided to the transceivers (e.g., at nodes f₁, f₂), may be obtained from a local oscillator signal or is a derivative signal of the local oscillator signal. For example, local oscillator signal may be provided by a voltage-controlled oscillator (VCO), e.g., a crystal OSC 224. As shown in FIG. 2, local oscillator high frequency signal provided to the transceiver may have a frequency at 5 GHz, which may be provided by a local crystal oscillator (OSC) 244. In some embodiments, crystal oscillator 244 may be a VCO (voltage-controlled oscillator) which generates periodic AC clock signals for which the frequency may be determined by the voltage. Whereas the frequency range of a VCO may not be wide enough to accommodate a desired frequency in wireless communication, a frequency multiplier may be used.

In some embodiments, RF circuit 200 may include a high frequency multiplier 246 to provide a high frequency signal of which the frequency may be a multiplication of that of the local oscillator signal. In non-limiting examples, the frequency multiplier 246 may be a tripler that provides signals at three times (3×) the frequency of the signal provided by the crystal OSC 244.

The inventors have recognized and acknowledged that existing high frequency multipliers typically use a mixer to combine multiple signals into a higher frequency signal. A mixer usually directly connects two or more signal lines of respective frequencies to generate an output signal that combines the frequencies of the signal lines. For example, Gilbert mixer may be used to mix two signals respectively of 8 GHz and 4 GHz and generate a 12 GHz signal. However, mixer-based frequency multipliers have drawbacks in that there are unwanted frequencies in the output signal. For example, a 12 GHz output signal may have 4 GHz and 8 GHz signals alongside. This causes interference with nearby frequencies and can significantly degrade the signal quality.

Existing solutions to unwanted frequencies in frequency multipliers include using filtering to remove unwanted frequencies. For example, a LC filter may be used to filter out unwanted frequencies. However, filter circuitry could result in extra large footprint and power consumption in circuit design. Further, logic gates are often used in frequency multipliers and they introduce signal delays, which may cause unwanted frequencies in output signals.

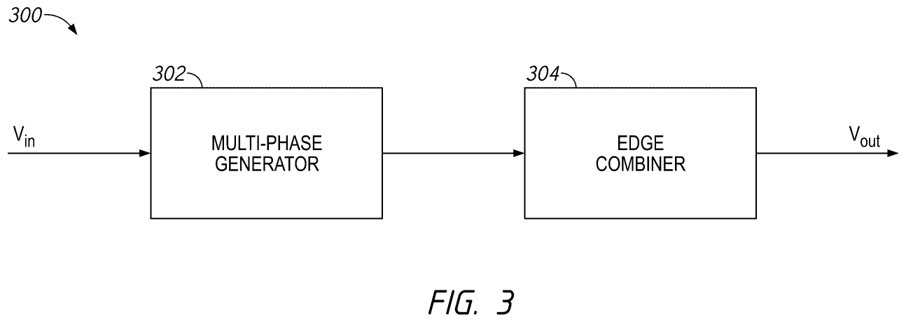

Accordingly, the inventors have developed improved high frequency multiplier. FIG. 3 is a schematic diagram of an example high frequency multiplier, according to some embodiments. Frequency multiplier 300 may be implemented in frequency multiplier 246 in RF circuit 200 (FIG. 2). For example, frequency multiplier 300 may be coupled to the one or more transceivers (e.g., transceivers 202-1, 202-2 in FIG. 2) and configured to provide the high frequency signal for modulation and demodulation.

As shown in FIG. 3, frequency multiplier 300 may include a multi-phase generator 302 and an edge combiner 304 coupled to the multi-phase generator. Input signal vᵢₙ is provided to multi-phase generator 302 which generates multiple delayed signals of the input signal, with each delayed signal having a respective delay. Edge combiner 304 may be configured to combine the clock edges of the multiple delayed signals from the multi-phase generator to generate a higher frequency output signal vₒᵤₜ. The clock edges may include rising edges and falling edges. Frequency multiplier 300 may be configured to have various odd-numbered multiplication factors, such as 3×, 5×, 7× etc.

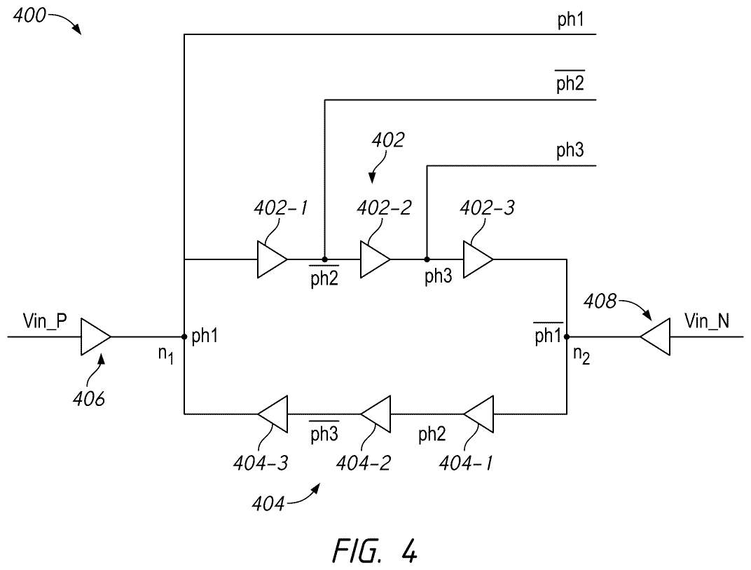

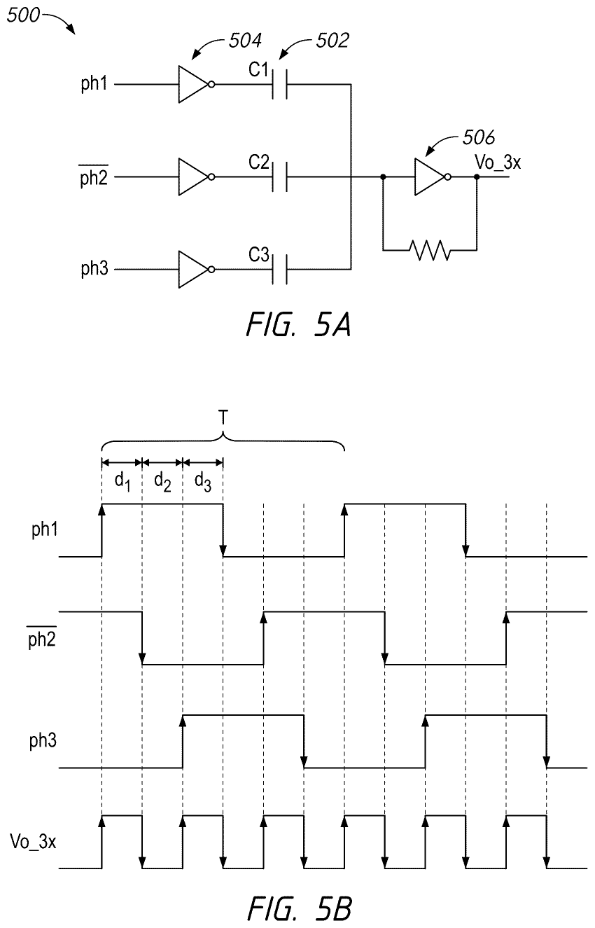

Examples are further provided to show detailed implementations of a frequency multiplier, with reference to FIGS. 4 and 5A. FIG. 4 is a schematic diagram of a multi-phase generator that can be used in a frequency tripler, according to some embodiments. FIG. 5A is a schematic diagram of an edge combiner that can be used in a frequency tripler, according to some embodiments.

In FIG. 4, multi-phase generator 400 may include a delay circuit 402 configured to generate multiple versions of the input signal, e.g., at multiple delayed signal lines. In some embodiments, delay circuit 402 may include multiple serially coupled delay cells, e.g., 402-1, 402-2, 402-3. In some embodiments, multi-phase generator 400 may include a plurality of output lines each at the output of a respective delay cell. Each delay cell may provide a respective time delay with respect to the input signal. Thus, the plurality of output lines are each provided a delayed signal having a respective delay with respect to the input signal, e.g., local oscillator signal. This is further described in detail in FIGS. 4 and 5B.

In FIG. 4, a delay cell may provide delayed signals from the input signal as well as inverted signal for differential scheme which provides signals of opposite polarities (e.g., positive and negative) at same time. For example, the output of delay cell 402-1 may provide an delayed signal with a certain time delay with respect to input signal ph1. Similarly, delay cell 402-2 may provide an output signal ph3 which is a delayed version of ^{¿}^{_{¿}}ₚₕ₂. Delay cell 402-3 may be configured in a similar manner. At the same time, the multi-phase generator may provide ^{¿}^{_{¿}}ₚₕ₁, ph2, and ^{¿}^{_{¿}}ₚₕ₃ that are inverted signals from ph1, ^{¿}^{_{¿}}ₚₕ₂, and ph3 respectively (see delay circuit 404 to be described further herein). These inverted signals can be used for differential scheme.

Examples of signal delays in delay circuit 402 are shown in FIG. 5B. As shown, delay circuit 402-1 may introduce a delay d₁, delay circuit 402-2 may introduce a delay d₂, and delay circuit 402-3 may introduce a delay d₃. In some embodiments, the delays of each delay cell of the delay circuit 402 may be configured to equally share half cycle of the input signal of the delay circuit, e.g., vᵢₙ (in FIG. 3). In the example frequence tripler implementation, there are three delay cells in delay circuit 402, thus the time delay of each delay cell may be set to d₁=d₂=d₃=⅙ T, where T is the cycle of input signal vᵢₙ. This results in the output signal vₒᵤₜ (in FIG. 3) to have a frequency that is three times that of the input signal.

As shown in FIG. 3, in some examples, input signal vᵢₙ may be a local oscillator signal in RF circuitry. For example, the input signal may be a local oscillator signal provided at a VCO (e.g., crystal OSC 244 in FIG. 2). In this example, the VCO signal may be of 4 GHz in frequency, whereas the output of the frequency multiplier 300 vₒᵤₜ may be of 12 GHz in frequency.

Returning to FIG. 4, multi-phase generator 400 may include another delay circuit 404, which may be configured in a similar manner as delay circuit 402. The input lines of the delay circuits 402, 404 may be respectively coupled to a first signal line and second signal line of opposite polarities, the first signal line and the second signal line configured to receive a differential signal of the input signal, e.g., v_{in_P} and v_{in_N}. Delay circuit 402 may be coupled to input signal line in a first polarity, e.g., v_{in_P}, to receive input signal v_{in_P}, whereas delay circuit 404 may be coupled to input signal line in a second polarity opposite the first polarity, e.g., v_{in_N}, to receive input signal v_{in_N}.

Similar to delay circuit 402, delay circuit 404 may include multiple serially coupled delay cells, e.g., 404-1, 404-2, 404-3. As shown, negative input signal v_{in_N} may be denoted as ^{¿}^{_{¿}}ₚₕ₁, which is the inverse of the positive input signal v_{in_P}, denoted as ph1. In delay circuit 404, each delay cell, e.g., 404-1, 404-2, 404-3, may include an output line to provide a respective time delay with respect to the input signal. In some examples, a delay cell may provide an inverse signal with a delay. For example, the output of delay cell 404-1 may provide an inversed signal with a time delay with respect to input signal ^{¿}^{_{¿}}ₚₕ₁, where the output signal ph2 is an inversed version of ^{¿}^{_{¿}}ₚₕ₁ with a delay. Similarly, delay cell 404-2 may provide an output signal ^{¿}^{_{¿}}ₚₕ₃ which is an inversed version of its input ph2 with a delay. Delay cell 404-3 may be configured in a similar manner. For example, the output signal ph1 is an inversed version of ^{¿}^{_{¿}}ₚₕ₃ with a delay. The time delay of each delay cell 404-1, 404-2, 404-3 may be configured in a similar manner as delay cells 402-1, 402-2, 402-3. For example, the time delay of each delay cell 404-1, 404-2, 404-3 may be equal to ⅙ of the cycle of v_{in_N} or v_{in_P}.

Having described delay circuits 402, 404, each of the delay cells in delay circuits may use any existing technologies, for example, using one or more transistors. Additionally, and/or alternatively, a delay circuit may include additional circuitry whether existing or later developed, configured to improve controllability of the delay circuit.

As shown in FIG. 4, delay circuits 402, 404 may be coupled in parallel and in reverse, where signal flows in each delay circuit are opposite. In this configuration, the output of delay circuit 404 is coupled to the input of delay circuit 402 (see node n₁). Conversely, the output of delay circuit 402 is coupled to the input of delay circuit 404 (see node n₂). The input lines of the delay circuits 402, 404 are respectively coupled to a first signal line and second signal line of, the first signal line and the second signal line configured to receive a differential signal of the oscillator signal, e.g., v_{in_P} and v_{in_N}. In such configuration, the delay cells become injection-locking delay cells in that a weaker signal (from any nodes in the delay circuits) may influence the frequency and phase of a stronger oscillator. This configuration may overcome the effect of phase mismatches in the delay circuits and provide frequency stabilization the output signal.

As a result, the delay caused by delay circuit 402 with respect to the input signal v_{in_P} equals the delay in the input signal v_{in_N} with respect to v_{in_P}. Because v_{in_P} and v_{in_N} are of different polarities, the delay caused by delay circuit 402 is half of the cycle of v_{in_P} and v_{in_N}. Similarly, the delay caused by delay circuit 404 with respect to the input signal v_{in_N} equals half of the cycle of v_{in_P} and v_{in_N}.

In some embodiments, delay circuit, e.g., 402 may include a driver, e.g., 406 coupled to the input signal line (e.g., v_{in_P}) to receive the input signal. Driver 406 may be coupled to the first delay cell in the delay circuit, e.g., delay cell 402-1 to provide the input signal to the delay circuit 402. Similarly, delay circuit 404 may include a driver, e.g., 408 coupled to the opposite input signal line in the differential input signal (e.g., v_{in_N}) to receive the input signal. Driver 408 may be coupled to the first delay cell in the delay circuit, e.g., delay cell 404-1 to provide the input signal to the delay circuit. In some embodiments, drivers 406, 408 may introduce the same delay.

FIG. 5A is a schematic diagram of an edge combiner 500 that can be used in a frequency tripler, according to some embodiments. In some embodiments, edge combiner 500 may be implemented in edge combiner 304 (in FIG. 3).

The inventors have recognized and acknowledged that existing edge combiners typically use flip-flops (e.g., D-flop) followed by a gate logic (e.g., NAND gates). These techniques, however, have high circuitry complexity and also introduce delay in the circuits. As discussed previously, delay in a high frequency multiplier may cause unwanted frequencies in the output signal and thus degrade the quality of the signal.

Accordingly, edge combiner described in the present disclosure includes simple circuitry that minimizes delay. In the example shown, edge combiner 500 may include multiple capacitors 502, the input of which are configured to be coupled respectively to the plurality of output lines of the multi-phase generator (e.g., 302 in FIG. 3). For example, in frequency tripler, edge combiner 500 may include three input lines of capacitors 502 are respectively coupled to different phase lines ph1, ^{¿}^{_{¿}}ₚₕ₂, and ph3 provided in multi-phase generator 400 (FIG. 4), where phase line ph1 is the input to the delay circuit 402, and phase lines ^{¿}^{_{¿}}ₚₕ₂ and ph3 are respectively output of delay cell 402-1 and 402-2. Edge combiner 500 may additionally include an amplifier 506 coupled to the multiple capacitors 502. In some examples, amplifier 506 may be an op-amp having a feedback loop and configured to output the frequency multiplied signal.

The edge combiner 500 as configured may follow the rising edges and falling edges of the delayed signal in any of the input lines. In the configuration shown in FIG. 5A, for each of the capacitors 502, if the input voltage changes, output follows the input and also changes in voltage. For example, in response to a rising edge at the input (e.g., voltage changes from low to high), output also changes from low to high. Conversely, in response to a falling edge at the input (e.g., voltage changes from high to low), the output also changes from high to low.

In the configuration shown, the amplifier 506 (e.g., an op-amp) is coupled to the outputs of the capacitors 502 to combine the output voltages of the capacitors. Whereas the input to the amplifier 506 may have a combined voltage depending on the outputs at the capacitors 502, the output of the amplifier 506 can have only two voltages: a low voltage or a high voltage. For example, in response to a rising edge at any capacitor, the combined voltage at the input of the amplifier 506 may increase, resulting in the output voltage change from low to high. Conversely, in response to a falling edge at any capacitor, the combined voltage at the input of the amplifier 506 may decrease, resulting in the output voltage change from high to low. As such, the output of the edge combiner follows the falling and rising edges of the input lines.

As shown in FIGS. 5A-5B, when the input lines of the edge combiner 500 are coupled respectively to the signal delay lines ph1, ^{¿}^{_{¿}}ₚₕ₂, and ph3 from the multi-phase generator, the output of the edge combiner v_{o_3x} follows the rising edges and falling edges of ph1, ^{¿}^{_{¿}}ₚₕ₂, and ph3. Because the delay in the ph1, ^{¿}^{_{¿}}ₚₕ₂, and ph3 each is ⅙ cycle of the input signal v_{in_P} and v_{in_N}, the resulting output of the edge combiner v_{o_3x} has a frequency of three times that of the input signal.

It is appreciated that in some variations, edge combiner 500 in FIG. 5A may include additional circuitry. For example, each of the capacitors 502 may be coupled to a respective driver 504, which may be coupled to a respective signal delay output line of the multi-phase generator. In other variations, edge combiner 500, along with multi-phase generator 400, may be configured to provide output signals with other multiplication factors. For example, multi-phase generator 400 may include five serially coupled delay cells in the delay circuit in a similar manner as shown in FIG. 4, and edge combiner 500 may include five capacitors respectively coupled to five signal delay output lines from the multi-phase generator 400 in a similar manner as shown in FIG. 5A. This configuration provides output signal that has five times frequency of that of the input signal. It is appreciated that the multi-phase generator and edge combiner as shown in FIGS. 3-5A can be configured into any suitable multiplier with odd numbered multiplications, such as 3×, 5×, 7×, 9× etc.

As described above and further herein, the capacitors used in edge combiner 500 can quickly follow the input signal without delay. This configuration thus addresses the drawbacks of circuitry delay associated with existing edge combiners and provides improved efficiency and effectiveness over the existing existing techniques, resulting in a high frequency signal with improved quality.

Returning to FIG. 2, although frequency multiplier 246 is shown to be disposed between a local oscillator (e.g., crystal OSC 244) and one or more transceivers (e.g., 202-1, 202-2), it is appreciated that frequency multiplier 246 may be configured to provide high frequency signal to any components in the RF circuit. In other variations, the frequence multiplier may be coupled to any signal line, instead of VCO signal, to receive an input signal and provide an output signal at any suitable multiplication factor in frequency.

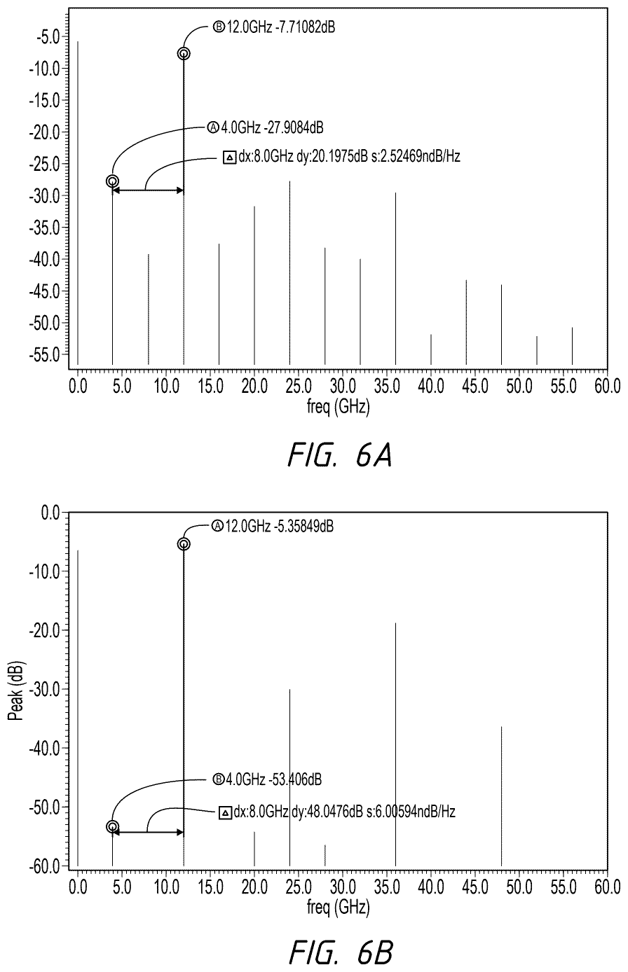

The various embodiments as described in FIGS. 1-5B provide improved high frequency multiplier over existing systems. FIGS. 6A-6B show comparison of simulated spur levels between a prior art frequency tripler and the example frequency tripler shown in FIGS. 3-5A, and show that the frequency multiplier as described in the present disclosure provides a higher spur level indicative of a higher quality signal. As shown, the spur level (e.g., difference between the amplitudes of the signal at a primary frequency and non-primary frequency) in existing systems with respect to 12 GHz and 4 GHz is about 20.2 dBc, whereas the spur level in the frequency multiplier as described in the present disclosure (e.g., in FIGS. 3-5A) is about 48 dBc.

Various embodiments described in the present disclosure provide advantages over existing systems in that embodiments of frequency multiplier as described in the present disclosure provide a higher spur level and thus high quality signal. As shown in FIGS. 3-5A, the frequency multiplier described herein does not use any mixer, but uses an edge combiner instead. Further, the frequency multiplier described herein does not use any logic gates or filter circuitry as in existing systems. As such, the frequency multiplier described herein does not have the drawbacks as in existing systems. The frequency multiplier described herein can be coupled to the transceivers in RF circuitry to provide high quality oscillator signals.

The indefinite articles “a” and “an,” as used herein in the specification and in the claims, unless clearly indicated to the contrary, should be understood to mean “at least one.” As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This allows elements to optionally be present other than the elements specifically identified within the list of elements to which the phrase “at least one” refers, whether related or unrelated to those elements specifically identified.

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

Use of ordinal terms such as “first,” “second,” “third,” etc., in the claims to modify a claim element does not by itself connote any priority, precedence, or order of one claim element over another or the temporal order in which acts of a method are performed. Such terms are used merely as labels to distinguish one claim element having a certain name from another element having a same name (but for use of the ordinal term).

The phraseology and terminology used herein is for the purpose of description and should not be regarded as limiting. The use of “including,” “comprising,” “having,” “containing”, “involving”, and variations thereof, is meant to encompass the items listed thereafter and additional items.

Having described several embodiments of the invention in detail, various modifications and improvements will readily occur to those skilled in the art. Such modifications and improvements are intended to be within the spirit and scope of the invention. Accordingly, the foregoing description is by way of example only, and is not intended as limiting.

1. An apparatus for communication in a wireless network, the apparatus comprising:
radio frequency (RF) circuitry comprising:
one or more transceivers respectively coupled to one or more antennas to transmit or receive RF signals, wherein each of the one or more transceivers is configured to convert between the RF signals and baseband signals based in part on a high frequency signal; and
a frequency multiplier coupled to the one or more transceiver and configured to provide the high frequency signal based in part on a local oscillator signal, the high frequency signal has a frequency that is odd-numbered multiplication of that of the local oscillator signal, the frequency multiplier comprising:
a multi-phase generator comprising a plurality of output lines and configured to generate a plurality of delayed signals respectively at the plurality of output lines, each delayed signal having a respective delay with respect to the local oscillator signal; and
an edge combiner coupled to the multi-phase generator, the edge combiner configured to provide the high frequency signal based in part on a rising edge or a falling edge of the plurality of delayed signals.

2. The apparatus of claim 1, wherein the multi-phase generator comprises a delay circuit comprising a plurality of serially coupled delay cells each configured to provide a delayed signal of the plurality of delayed signals at a respective output line of the plurality of output lines.

3. The apparatus of claim 2, wherein the multi-phase generator further comprises an additional delay circuit comprising a plurality of serially coupled delay cells, wherein the additional delay circuit and the delay circuit are coupled in parallel and in reverse such that an input line to the delay circuit is coupled to an output line of the additional delay circuit and an input line to the additional delay circuit is coupled to an output line of the delay circuit.

4. The apparatus of claim 3, wherein the input lines of the delay circuit and the additional delay circuit are respectively coupled to a first signal line and second signal line of opposite polarities, the first signal line and the second signal line configured to receive a differential signal of the local oscillator signal.

5. The apparatus of claim 1, wherein the edge combiner comprises:
a plurality of capacitors respectively configured to be coupled to a respective output line of the plurality of output lines of the multi-phase generator to receive the plurality of delayed signals; and
an amplifier coupled to the plurality of capacitors and configured to provide the high frequency signal based on the plurality of delayed signals.

6. The apparatus of claim 5, wherein each of the plurality of capacitors is configured so that an output of the capacitor follows a corresponding delayed signal of the plurality of delayed signals.

7. The apparatus of claim 5, wherein the amplifier is configured to:
receive an input voltage based on outputs of the plurality of capacitors, the input voltage changes responsive to a rising edge or a falling edge in the plurality of delayed signals; and
provide the high frequency signal based on the input voltage.

8. The apparatus of claim 5, wherein the amplifier is configured to:
responsive to a rising edge signal in a delayed signal of the plurality of delayed signals, changes output from a low voltage to a high voltage; and
responsive to a falling edge signal in a delayed signal of the plurality of delayed signals, changes output from a high voltage to a low voltage.

9. The apparatus of claim 2, wherein a number of the plurality of serially coupled delay cells is an odd number, and the time delays of the plurality of serially coupled delay cells equally share half cycle of the local oscillator signal.

10. The apparatus of claim 9, wherein the number of the plurality of serially coupled delay cells is three whereby the high frequency signal has a frequency that is three times that of the local oscillator signal.

11. A radio frequency (RF) circuitry comprising:
one or more transceivers respectively coupled to one or more antennas to transmit or receive RF signals, wherein each of the one or more transceivers is configured to convert between the RF signals and baseband signals based in part on a high frequency signal; and
a frequency multiplier coupled to the one or more transceiver and configured to provide the high frequency signal based in part on a local oscillator signal, the high frequency signal has a frequency that is odd-numbered multiplication of that of the local oscillator signal, the frequency multiplier comprising:
a multi-phase generator comprising a plurality of output lines and configured to generate a plurality of delayed signals respectively at the plurality of output lines, each delayed signal having a respective delay with respect to the local oscillator signal; and
an edge combiner coupled to the multi-phase generator, the edge combiner configured to provide the high frequency signal based in part on a rising edge or a falling edge of the plurality of delayed signals.

12. The RF circuitry of claim 11, wherein the multi-phase generator comprises a delay circuit comprising a plurality of serially coupled delay cells each configured to provide a delayed signal of the plurality of delayed signals at a respective output line of the plurality of output lines.

13. The RF circuitry of claim 12, wherein the multi-phase generator further comprises an additional delay circuit comprising a plurality of serially coupled delay cells, wherein the additional delay circuit and the delay circuit are coupled in parallel and in reverse such that an input line to the delay circuit is coupled to an output line of the additional delay circuit and an input line to the additional delay circuit is coupled to an output line of the delay circuit.

14. The RF circuitry of claim 11, wherein the edge combiner comprises:
a plurality of capacitors respectively configured to be coupled to a respective output line of the plurality of output lines of the multi-phase generator to receive the plurality of delayed signals; and
an amplifier coupled to the plurality of capacitors and configured to provide the high frequency signal.

15. The RF circuitry of claim 14, wherein each of the plurality of capacitors is configured so that an output of the capacitor follows a corresponding delayed signal of the plurality of delayed signals.

16. The RF circuitry of claim 14, wherein the amplifier is configured to:
receive an input voltage based on outputs of the plurality of capacitors, the input voltage changes responsive to a rising edge or a falling edge in the plurality of delayed signals; and
provide the high frequency signal based on the input voltage.

17. The RF circuitry of claim 14, wherein the amplifier is configured to:
responsive to a rising edge signal in a delayed signal of the plurality of delayed signals, changes output from a low voltage to a high voltage; and
responsive to a falling edge signal in a delayed signal of the plurality of delayed signals, changes output from a high voltage to a low voltage.

18. The RF circuitry of claim 12, wherein a number of the plurality of serially coupled delay cells is an odd number, and the time delays of the plurality of serially coupled delay cells equally share half cycle of the local oscillator signal.

19. A frequency multiplier for use in a wireless transceiver, the frequency multiplier comprising:
a multi-phase generator comprising a plurality of output lines and configured to generate a plurality of delayed signals respectively at the plurality of output lines, each delayed signal having a respective delay with respect to a first signal; and
an edge combiner coupled to the multi-phase generator, the edge combiner configured to provide a second signal based in part on a rising edge or a falling edge in the plurality of delayed signals;
wherein the second signal has a frequency that is odd-numbered multiplication of that of the first signal.

20. The frequency multiplier of claim 19, wherein the edge combiner comprises:
a plurality of capacitors respectively configured to be coupled to a respective output line of the plurality of output lines of the multi-phase generator to receive the plurality of delayed signals; and
an amplifier coupled to the plurality of capacitors and configured to provide the high frequency signal.

21. The frequency multiplier of claim 20, wherein each of the plurality of capacitors is configured so that an output of the capacitor follows a corresponding delayed signal of the plurality of delayed signals.

22. The frequency multiplier of claim 20, wherein the amplifier is configured to:
receive an input voltage based on outputs of the plurality of capacitors, the input voltage changes responsive to a rising edge or a falling edge in the plurality of delayed signals; and
provide the high frequency signal based on the input voltage.

23. The frequency multiplier of claim 20, wherein the amplifier is configured to:
responsive to a rising edge signal in a delayed signal of the plurality of delayed signals, changes output from a low voltage to a high voltage; and
responsive to a falling edge signal in a delayed signal of the plurality of delayed signals, changes output from a high voltage to a low voltage.

24. The frequency multiplier of claim 19, wherein the multi-phase generator comprises a delay circuit comprising a plurality of serially coupled delay cells each configured to provide a delayed signal of the plurality of delayed signals at a respective output line of the plurality of output lines, wherein a number of the plurality of serially coupled delay cells is an odd number, and the time delays of the plurality of serially coupled delay cells equally share half cycle of the local oscillator signal.
